(19) United States
(12) Patent Application Publication
(10) Pub. No.: US 2023/0217648 A1
(43) Pub. Date: Jul. 6, 2023

(54) SEMICONDUCTOR STRUCTURE AND MANUFACTURING METHOD THEREOF, DATA STORAGE DEVICE AND DATA READ-WRITE DEVICE

(71) Applicant: CHANGXIN MEMORY TECHNOLOGIES, INC., Hefei City (CN)

(72) Inventor: Xiang LIU, Hefei City (CN)

(21) Appl. No.: 17/661,355

(22) Filed: Apr. 29, 2022

Related U.S. Application Data
(63) Continuation of application No. PCT/CN2022/081545, filed on Mar. 17, 2022.

(30) Foreign Application Priority Data
Jan. 6, 2022 (CN) 202210013059.9

(51) Int. Cl. H01L 27/108; G11C 11/408

(52) U.S. Cl. CPC H01L 27/10823; G11C 11/4085; H01L 27/10897; H01L 27/10876

(57) ABSTRACT

Embodiments of the present disclosure relate to a semiconductor structure and a manufacturing method thereof, a data storage device and a data read-write device. The semiconductor structure includes: a substrate, a plurality of active regions separated from each other being formed in the substrate; a trench, located in the active region; a first gate structure, located in the trench, and configured to be applied with a first applied voltage; a second gate structure, located in the trench, and located above the first gate structure, and configured to be applied with a second applied voltage, the second applied voltage being greater than the first applied voltage; and an insulating isolation layer, located in the trench, and located between the first gate structure and the second gate structure.

### CROSS-REFERENCE TO RELATED APPLICATIONS

This is a continuation of International Application No. PCT/CN2022/081545, filed on Mar. 17, 2022, which claims the priority to Chinese Patent Application 202210013059.9, filed with China National Intellectual Property Administration (CNIPA) on Jan. 6, 2022. The entire contents of International Application No. PCT/CN2022/081545 and Chinese Patent Application 202210013059.9 are incorporated herein by reference.

### TECHNICAL FIELD

Embodiments of the present disclosure relate to the technical field of semiconductors, and in particular to a semiconductor structure and a manufacturing method thereof, a data storage device and a data read-write device.

### BACKGROUND

Dynamic random access memories (DRAMs) are commonly-used semiconductor memory devices in computers. Access transistors in present DRAMs usually adopt buried word lines (WLs), but a gate-induced drain leakage (GIDL) current is caused easily in manufacture of the buried WLs. The GIDL is considered as a main way for electric leakage of the DRAMs, and the magnitude of the GIDL current depends directly on electric field of overlapping region between the WL and the source/drain.

Materials (such as polycrystalline silicon) with a low work function have been used to substitute some metal WL materials (such as tungsten or titanium nitride) with a high work function in existing processes, which can effectively reduce the electric fields of the overlapping regions and thus reduce the GIDL current.

The more the metal WL materials substituted by the polycrystalline silicon, the less the GIDL. However, when the metal WL materials are substituted by the polycrystalline silicon, the resistances of the WLs are increased due to a high resistivity of the polycrystalline silicon, thus lowering turn-on speeds of the access transistors and affecting access speeds of the devices.

### SUMMARY

Embodiments of the present disclosure provide a semiconductor structure and a manufacturing method thereof, a data storage device and a data read-write device.

According to an aspect, an embodiment of the present disclosure provides a semiconductor structure, including:

a substrate, a plurality of active regions separated from each other being formed in the substrate;

a trench, located in the active region;

a first gate structure, located in the trench, and configured to be applied with a first applied voltage;

a second gate structure, located in the trench, and located above the first gate structure, and configured to be applied with a second applied voltage, the second applied voltage being greater than the first applied voltage; and

an insulating isolation layer, located in the trench, and located between the first gate structure and the second gate structure.

According to another aspect, an embodiment of the present disclosure provides a method of manufacturing a semiconductor structure, including:

providing a substrate, a plurality of active regions separated from each other being formed in the substrate;

forming a plurality of trenches in the active regions;

forming a first gate structure, an insulating isolation layer and a second gate structure in the trench, wherein the second gate structure is located above the first gate structure, and the insulating isolation layer is located between the first gate structure and the second gate structure; and

forming a first word line driver and a second word line driver in the substrate, wherein the first word line driver is electrically connected to the first gate structure, and configured to apply a first applied voltage to the first gate structure; and the second word line driver is electrically connected to the second gate structure, and configured to apply a second applied voltage to the second gate structure; and the second applied voltage is greater than the first applied voltage.

An embodiment of the present disclosure further provides a data storage device, including the semiconductor structure provided by any one of the above-described embodiments.

An embodiment of the present disclosure further provides a data read-write device, including the semiconductor structure provided by any one of the above-described embodiments.

The details in one or more embodiments of the present disclosure will be illustrated in the following drawings and description. Other features in the embodiments of the present disclosure will become apparent from the description, drawings and claims.

### BRIEF DESCRIPTION OF THE DRAWINGS

To describe the technical solutions in the embodiments of the present disclosure more clearly, the accompanying drawings required to describe the embodiments are briefly described below. Apparently, the accompanying drawings described below are only some embodiments of the present disclosure. Those of ordinary skill in the art may further obtain accompanying drawings of other embodiments based on these accompanying drawings without creative efforts.

FIG. 1 illustrates a flowchart of a method of manufacturing a semiconductor structure according to an embodiment of the present disclosure;

FIG. 2 illustrates a schematic sectional view of a structure obtained in Step S10 in a method of manufacturing a semiconductor structure according to an embodiment of the present disclosure;

FIG. 3 illustrates a schematic sectional view of a structure obtained in Step S20 in a method of manufacturing a semiconductor structure according to an embodiment of the present disclosure;

FIG. 4 illustrates a flowchart of Step S30 in a method of manufacturing a semiconductor structure according to an embodiment of the present disclosure;

FIG. 5 to FIG. 13 are schematic sectional views of structures obtained in various steps of Step S30 in a method of manufacturing a semiconductor structure according to an embodiment of the present disclosure, in which FIG. 13 is also a schematic structural view of a semiconductor structure according to an embodiment of the present disclosure; and

FIG. 14 illustrates a schematic structural view of a semiconductor structure according to another embodiment of the present disclosure.

### DETAILED DESCRIPTION

To facilitate the understanding on embodiments of the present disclosure, the embodiments of the present disclosure are described more completely below with reference to the accompanying drawings. Preferred embodiments of the present disclosure are shown in the accompanying drawings. However, the embodiments of the present disclosure may be implemented in various forms without being limited to the embodiments described herein. On the contrary, these embodiments are provided to make the embodiments of the present disclosure more thorough and comprehensive.

Unless otherwise defined, all technical and scientific terms used herein have the same meaning as commonly understood by those skilled in the technical field of the embodiments of the present disclosure. The terms used in specifications of the embodiments of the present disclosure are merely for the purpose of describing specific embodiments, rather than limiting the embodiments of the present disclosure. The term “and/or” used herein includes any and all combinations of one or more of the associated listed items.

It should be understood that when an element or a layer is described as “being on”, “being connected to” or “being coupled to” another element or layer, it can be on, connected to, or coupled to the another element or layer directly, or intervening elements or layers may be present. On the contrary, when an element is described as “being directly on”, “being directly connected to” or “being directly coupled to” another element or layer, there are no intervening elements or layers. It should be understood that although terms such as first, second, and third may be used to describe various elements, components, regions, layers and/or sections, these elements, components, regions, layers and/or sections should not be limited by these terms. These terms are only used to distinguish one element, component, region, layer or section from another element, component, region, layer or section. Therefore, without departing from the teachings of the present disclosure, the first element, component, region, layer or section discussed below may be a second element, component, region, layer or section.

Spatial relationship terms such as “under”, “beneath”, “lower”, “below”, “above”, and “upper” can be used herein to conveniently describe the relationship shown in the figure between one element or feature and another element or feature. It should be understood that in addition to the orientations shown in the figure, the spatial relationship terms are intended to further include different orientations of used and operated devices. For example, if a device in the accompanying drawings is turned over, and then described as being “beneath another element”, “below it”, or “under it”, the device or feature is oriented “on” another element or feature. Therefore, the exemplary terms “beneath” and “under” may include two orientations of above and below. The device may be otherwise oriented (rotated by 90 degrees or other orientations), and the spatial description used herein is interpreted accordingly.

The purpose of the terms used herein is only to describe specific embodiments rather than limit the embodiments of the present disclosure. In this specification, the singular forms of “a”, “an” and “the/this” also include plural forms, unless clearly indicated otherwise. It should also be understood that terms “include” and/or “comprise”, when used in this specification, determine the presence of features, integers, steps, operations, elements and/or components, but do not exclude the presence or addition of one or more other features, integers, steps, operations, elements, components and/or groups. In this specification, the term “and/or” includes any and all combinations of related listed items.

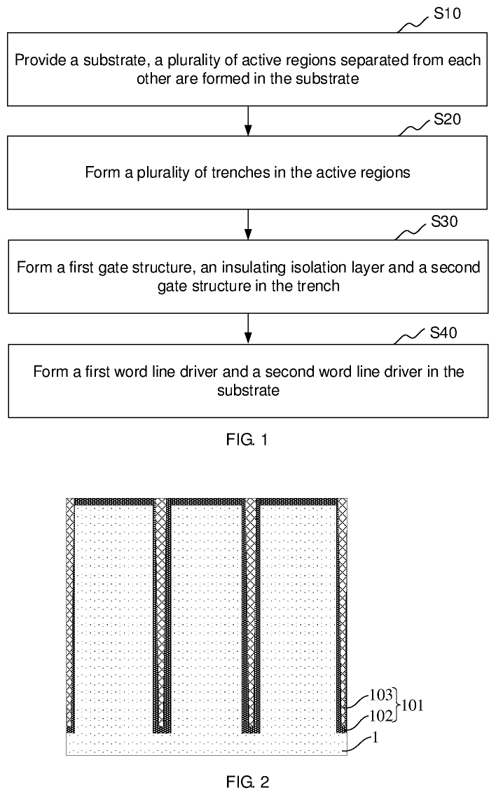

The present disclosure is described with reference to FIG. 1 to FIG. 14. It should be noted that, the drawings provided in the embodiments merely illustrate the basic concepts of the present disclosure schematically. Although the drawings only show components related to the present disclosure rather than being drawn according to the quantities, shapes, and sizes of components in actual implementation, patterns, quantities, and proportions of components in actual implementation may be changed randomly, and the component layout may be more complex.

Referring to FIG. 1, an embodiment of the present disclosure provides a method of manufacturing a semiconductor structure. Referring to FIG. 1, the manufacturing method may include:

Step S10: Provide a substrate, a plurality of active regions separated from each other are formed in the substrate.

Step S20: Form a plurality of trenches in the active regions.

Step S30: Form a first gate structure, an insulating isolation layer and a second gate structure in the trench. Specifically, the second gate structure is located above the first gate structure, and the insulating isolation layer is located between the first gate structure and the second gate structure.

Step S40: Form a first WL driver and a second WL driver in the substrate. The first WL driver is electrically connected to the first gate structure, and configured to apply a first applied voltage to the first gate structure. The second WL driver is electrically connected to the second gate structure, and configured to apply a second applied voltage to the second gate structure. The second applied voltage is greater than the first applied voltage.

Specifically, referring also to FIG. 1, the first gate structure, the insulating isolation layer and the second gate structure are formed in the trench, and the first gate structure and the second gate structure are isolated from each other through the insulating isolation layer, such that the first gate structure and the second gate structure can form a dual gate structure. As the voltage applied to the second gate structure is greater than the voltage applied to the first gate structure, the GIDL can be reduced. With the voltage applied to the second gate structure greater than the voltage applied to the first gate structure, more electrons can further be accumulated in an overlapping region between the WL and the source/drain to decrease a resistance of the WL and boost a driving current. Moreover, with the reduced GIDL, the dual gate structure formed in the WL trench of the semiconductor structure can be higher appropriately to further boost the driving current, thus improving the access speed of the device.

The method of manufacturing a semiconductor structure provided by the embodiment of the present disclosure will be described below in detail with reference to FIG. 2 to FIG. 13.

In Step S10, provide a substrate 1, a plurality of active regions separated from each other (not shown in FIG. 2) being formed in the substrate 1, as shown in FIG. 2.

It is to be noted that there are no limits made on a material of the substrate 1 in the embodiment of the present disclosure. The substrate 1 may be made of a material including but not limited to silicon (Si), silicon carbide (SiC), sapphire, gallium nitride (GaN) or gallium arsenide (GaAs). That is, the substrate 1 may include, but is not limited to, a silicon layer, a silicon carbide layer, a sapphire layer, a gallium nitride layer or a gallium arsenide layer. As an example, the substrate 1 includes a silicon layer.

A plurality of shallow trench isolation (STI) structures 101 may be formed in the substrate 1. These STI structures 101 isolate a plurality of active regions separated from each other in the substrate 1.

There are no limits made on a method for forming the STI structure 101 in the embodiment of the present disclosure. As an example, a patterned mask structure may be formed on the substrate 1. The substrate 1 is etched to form a steep trench between adjacent device regions. An oxide is filled in the trench to form the STI structure 101. Optionally, silicon oxide (SiO₂) may be filled to form the STI structure 101.

As an example, a first filling layer 102 and a second filling layer 103 may be sequentially formed on a bottom and a sidewall of the trench. Referring also to FIG. 2, the first filling layer 102 covers the sidewall of the trench, and the second filling layer 103 covers a sidewall of the first filling layer 102 and fills the trench to the full. There are no limits made on materials of the first filling layer 102 and the second filling layer 103 in the embodiment of the present disclosure. As an example, the first filling layer 102 may include a silicon oxide layer, and the second filling layer 103 may include a silicon nitride layer.

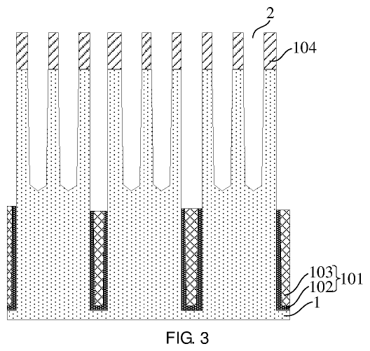

In Step S20, form a plurality of trenches 2 in the active regions, as shown in FIG. 3.

As an example, the substrate 1 may be photoetched to form the plurality of trenches 2.

Referring also to FIG. 3, as an example, before Step S20, the method of manufacturing a semiconductor structure may further include:

Form an insulating layer 104 on a surface of the first filling layer 102 and a surface of the second filling layer 103.

It is to be understood that there are no limits made on a material of the insulating layer 104 in the embodiment of the present disclosure. As an example, the insulating layer 104 and the first filling layer 102 may be made of a same material.

As an example, after Step S20 and before Step S30, the method of manufacturing a semiconductor structure may further include:

Form a source and a drain in the active region, the source and the drain are located at two opposite sides of the trench 2.

It is to be understood that the source and the drain in the embodiment of the present disclosure are a source and a drain formed in the active region by diffusion and doping.

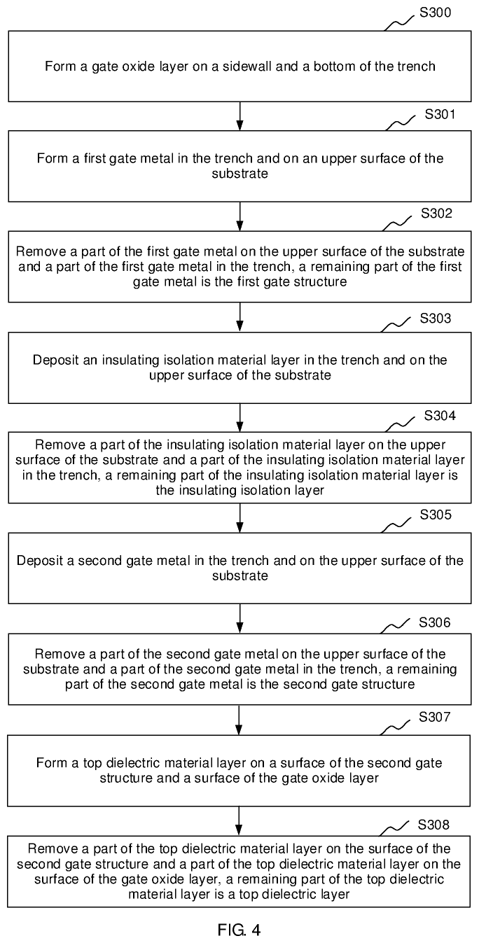

In Step S30, form a first gate structure 211, a second gate structure 212 and an insulating isolation layer 213 in the trench 2, as shown in FIG. 4 to FIG. 13. The second gate structure 212 is located above the first gate structure 211, and the insulating isolation layer 213 is located between the first gate structure 211 and the second gate structure 212.

Regarding Step S30, as an example, referring to FIG. 4, Step S30 may include:

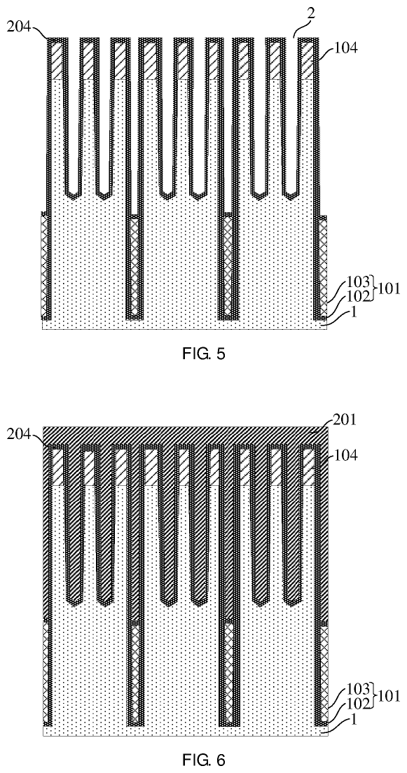

Step S301: Form a first gate metal 201 in the trench 2 and on an upper surface of the substrate 1, as shown in FIG. 6.

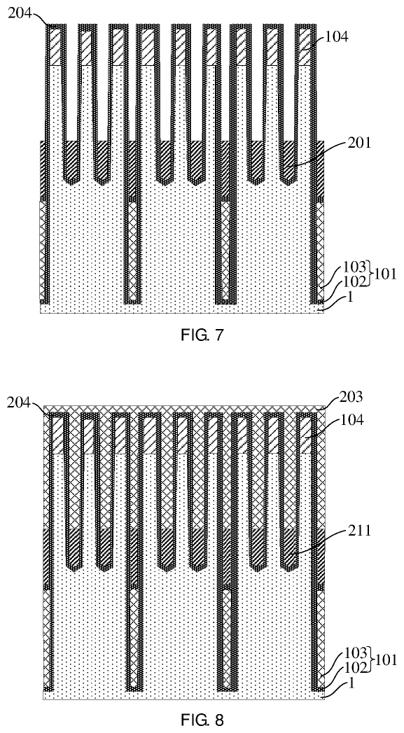

Step S302: Remove a part of the first gate metal 201 on the upper surface of the substrate 1 and a part of the first gate metal 201 in the trench 2, a remaining part of the first gate metal 201 is the first gate structure 211, as shown in FIG. 7.

Step S303: Deposit an insulating isolation material layer 203 in the trench 2 and on the upper surface of the substrate 1, as shown in FIG. 8.

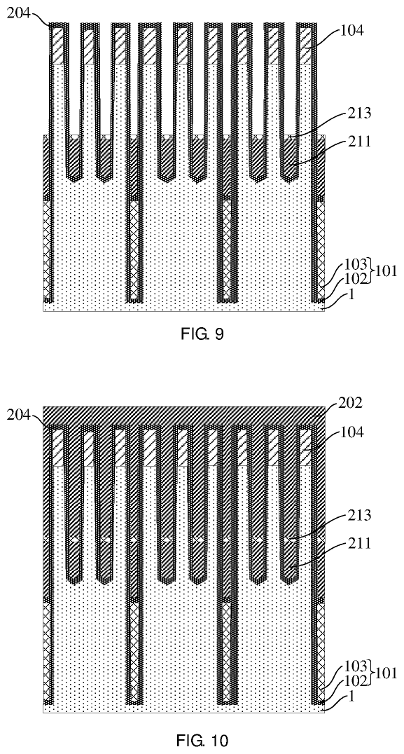

Step S304: Remove a part of the insulating isolation material layer 203 on the upper surface of the substrate 1 and a part of the insulating isolation material layer 203 in the trench 2, a remaining part of the insulating isolation material layer 203 is the insulating isolation layer 213, as shown in FIG. 9.

Step S305: Deposit a second gate metal 202 in the trench 2 and on the upper surface of the substrate 1, as shown in FIG. 10.

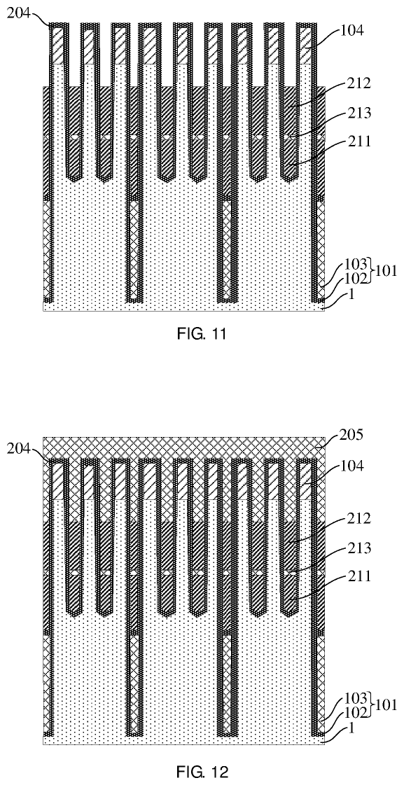

Step S306: Remove a part of the second gate metal 202 on the upper surface of the substrate 1 and a part of the second gate metal 202 in the trench 2, a remaining part of the second gate metal 202 is the second gate structure 212, as shown in FIG. 11.

There are no limits made on a material of the first gate metal 201 and the second gate metal 202 in the embodiment of the present disclosure. Both the first gate metal 201 and the second gate metal 202 may include, but are not limited to, titanium nitride, tungsten or polycrystalline silicon.

As an example, both the first gate metal 201 and the second gate metal 202 include the titanium nitride.

Specifically, the titanium nitride has a lower resistivity than other gate materials. By taking the titanium nitride as the first gate metal 201 and the second gate metal 202, the delay of electrical signals in conduction can be prevented, and the power consumption can be reduced. Meanwhile, the titanium nitride serves as a desirable diffusion barrier to prevent interdiffusion through silicides.

There are no limits made on a material of the insulating isolation material layer 203 and the insulating isolation layer 213 in the embodiment of the present disclosure. As an example, both the insulating isolation material layer 203 and the insulating isolation layer 213 may be made of a material including but not limited to silicon oxide or silicon nitride. That is, both the insulating isolation material layer 203 and the insulating isolation layer 213 may include, but are not limited to, a silicon oxide layer and a silicon nitride layer.

As an example, both the insulating isolation material layer 203 and the insulating isolation layer 213 are made of a material including silicon nitride. That is, both the insulating isolation material layer 203 and the insulating isolation layer 213 include a silicon nitride layer. The silicon nitride is a high-performance electrical insulating material with a high thermal conductivity. By taking the silicon nitride as the insulating isolation material layer 203 in the method of manufacturing a semiconductor structure in the embodiment, the dielectric coefficient is small, the dielectric breakdown voltage is high, and the thermal insulation of the substrate 1 is not damaged seriously.

Referring to FIG. 5, as an example, before Step S301, Step S30 may further include:

Step S300: Form a gate oxide layer 204 on a sidewall and a bottom of the trench 2.

There are no limits made on a material of the gate oxide layer 204 in the embodiment of the present disclosure. The gate oxide layer 204 may be made of a material including but not limited to silicon oxide or silicon oxynitride. As an example, the material of the gate oxide layers 204 includes the silicon oxide.

Specifically, since the silicon oxide has a desirable insulativity and can contact the surface of the trench 2 at a low surface state density, the silicon oxide as the gate oxide layer 204 can effectively improve the performance of the device.

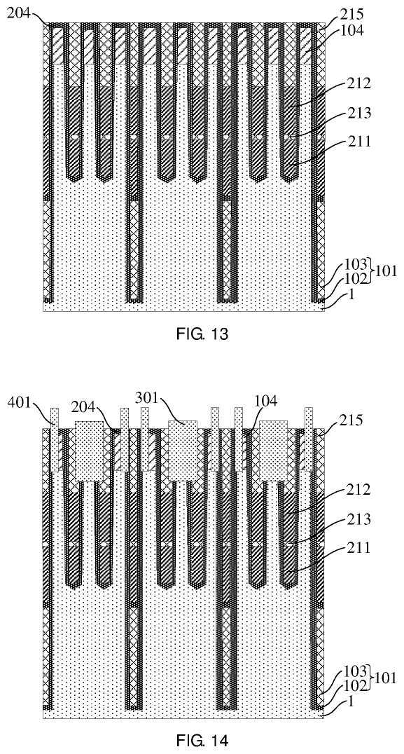

Referring also to FIG. 12 to FIG. 13, as an example, Step S30 may further include:

Step S307: Form a top dielectric material layer 205 on a surface of the second gate structure 212 and a surface of the gate oxide layer 204, as shown in FIG. 12.

Step S308: Remove a part of the top dielectric material layer 205 on the surface of the second gate structure 212 and a part of the top dielectric material layer 205 on the surface of the gate oxide layer 204, a remaining part of the top dielectric material layer 205 is a top dielectric layer 215, as shown in FIG. 13.

There are no limits made on a material of the top dielectric material layer 205 and the top dielectric layer 215 in the embodiment of the present disclosure. As an example, the top dielectric material layer 205 and the top dielectric layer 215 may be made of a material including but not limited to titanium nitride. That is, the top dielectric material layers 205 and the top dielectric layers 215 each may include, but are not limited to, a titanium nitride layer.

Referring also to FIG. 13, an embodiment of the present disclosure provides a semiconductor structure, including a substrate 1, trenches (not shown in FIG. 13), a first gate structure 211, a second gate structure 212 and an insulating isolation layer 213.

A plurality of active regions separated from each other are formed in the substrate 1. The trench is located in the active region. The first gate structure 211, the second gate structure 212 and the insulating isolation layer 213 are located in the trench. The first gate structure 211 is configured to be applied with a first applied voltage. The second gate structure 212 is located above the first gate structure 211 and is configured to be applied with a second applied voltage. The second applied voltage is greater than the first applied voltage. The insulating isolation layer 213 is located between the first gate structure 211 and the second gate structure 212.

Specifically, the first gate structure 211 and the second gate structure 212 are isolated from each other through the insulating isolation layer 213 to form a dual gate structure. As the voltage applied to the second gate structure is greater than the voltage applied to the first gate structure, the GIDL can be reduced. With the voltage applied to the second gate structure greater than the voltage applied to the first gate structure, more electrons can further be accumulated in an overlapping region between the WL and the source/drain to decrease a resistance of the WL and boost a driving current. Moreover, with the reduced GIDL, the dual gate structure formed in the WL trench of the semiconductor structure can be higher appropriately to further boost the driving current, thus improving the access speed of the device.

As an example, the semiconductor structure may further include a first WL driver and a second WL driver.

The first WL driver is electrically connected to the first gate structure 211, and configured to apply a first applied voltage to the first gate structure 211. The second WL driver is electrically connected to the second gate structure 212, and configured to apply a second applied voltage to the second gate structure 212.

It is to be understood that the voltage of the second gate structure 212 is slightly higher than that of the first gate structure 211 all the time regardless of a data storage operation or a data read-write operation of the semiconductor structure. For example, in response to the data storage operation of the semiconductor structure, the first applied voltage may be −0.2 V, while the second applied voltage may be −0.1 V to 0.1 V. In response to the data read-write operation of the semiconductor structure, the first applied voltage may be 3.0 V, while the second applied voltage may be 3.1 V to 3.3 V.

Referring also to FIG. 13, as an example, a plurality of STI structures 101 may be formed in the substrate 1. These STI structures 101 isolate a plurality of active regions separated from each other in the substrate 1.

It is to be noted that the specific structure of the STI structure 101 is not emphasized in the embodiment of the present disclosure, and that structure may be understood with reference to the prior art and will not be repeated herein in the embodiment of the present disclosure.

As an example, there may be a plurality of the trenches, and the plurality of the trenches are spaced apart.

There are no limits made on a material of the first gate structure 211 and the second gate structure 212 in the embodiment of the present disclosure. As an example, the first gate structure 211 may include a first gate metal. The first gate metal may include, but is not limited to, titanium nitride, tungsten or polycrystalline silicon. As an example, the second gate structure 212 may include a second gate metal. The second gate metal may include, but is not limited to, titanium nitride, tungsten or polycrystalline silicon.

As an example, both the first gate metal and the second gate metal include the titanium nitride. That is, both the first gate structure 211 and the second gate structure 212 include a titanium nitride layer. The titanium nitride has a lower resistivity than other gate materials.

Specifically, as both the first gate structure 211 and the second gate structure 212 include the titanium nitride layer, the delay of electrical signals in conduction can be prevented, and the power consumption can be reduced. Meanwhile, the titanium nitride serves as a desirable diffusion barrier to prevent interdiffusion through silicides.

As an example, a thickness of the insulating isolation layer 213 may be in the range of 5 nm to 8 nm. As an example, a thickness of the insulating isolation layer 213 may be 5 nm, 6 nm, 7 nm or 8 nm. It is to be understood that the above data merely serves as an example. In actual embodiments, the thickness of the insulating isolation layer 213 is not limited to the above values.

There are no limits made on a material of the insulating isolation layer 213 in the embodiment of the present disclosure. As an example, the insulating isolation layer 213 may be made of a material including but not limited to silicon oxide or silicon nitride. That is, the insulating isolation layer 213 may include, but is not limited to, a silicon oxide layer or a silicon nitride layer.

As an example, the insulating isolation layer 213 may be made of a material including silicon nitride. That is, the insulating isolation layer 213 may include a silicon nitride layer.

The silicon nitride is a high-performance electrical insulating material with a high thermal conductivity. Specifically, the insulating isolation layer 213 includes the silicon nitride layer, and the silicon nitride layer has a small dielectric coefficient and a high dielectric breakdown voltage and does not damage the thermal insulation of the substrate 1 seriously.

As an example, referring to FIG. 14, the semiconductor structure may further include a source (not shown in FIG. 14), a source contact structure 301, a drain (not shown in FIG. 14) and a drain contact structure 401.

It is to be understood that the source and the drain in the embodiment of the present disclosure are a source and a drain formed in the active region by diffusion and doping.

Specifically, the source is located in the active region, and located at a side of the first gate structure 211 and the second gate structure 212. The source may include a source region at a side of the first gate structure 211 and the second gate structure 212. The source contact structure 301 is electrically connected to the source. The drain is located in a same active region with the source and at a side of the first gate structure 211 and the second gate structure 212 away from the source. The drain may include a drain region located in a same active region and at a side of the first gate structure 211 and the second gate structure 212 away from the source. The drain contact structure 401 is electrically connected to the drain.

Referring also to FIG. 13, as an example, the semiconductor structure may further include a gate oxide layer 204.

Specifically, the gate oxide layer 204 is located on a sidewall and a bottom of the trench. On the basis of the above embodiment, the first gate structure 211, the insulating isolation layer 213 and the second gate structure 212 may be located on a surface of the gate oxide layer 204.

There are no limits made on a material of the gate oxide layer 204 in the embodiment of the present disclosure. The gate oxide layer 204 may be made of a material including but not limited to silicon oxide or silicon oxynitride. As an example, the material of the gate oxide layers 204 includes the silicon oxide.

Specifically, since the silicon oxide has a desirable insulativity and can contact the surface of the trench 2 at a low surface state density, the silicon oxide as the gate oxide layer 204 can achieve the better performance of the device.

Referring also to FIG. 13, as an example, the semiconductor structure may further include a top dielectric layer 215.

Specifically, the top dielectric layer 215 is located in the trench and on the second gate structure 212.

There are no limits made on a material of the top dielectric layer 215 in the embodiment of the present disclosure. As an example, the top dielectric layer 215 may be made of a material including but not limited to titanium nitride. That is, the top dielectric layer 215 may include, but is not limited to, a titanium nitride layer.

An embodiment of the present disclosure provides a data storage device, including the semiconductor structure provided by the above embodiment.

The data storage device provided by the embodiment of the present disclosure includes the semiconductor structure described in the above embodiment. The technical effects realized by the semiconductor structure can also be achieved by the data storage device, and will not be described in detail herein.

An embodiment of the present disclosure provides a data read-write device, including the semiconductor structure provided by the above embodiment.

The data read-write device provided by the embodiment of the present disclosure includes the semiconductor structure described in the above embodiment. The technical effects realized by the semiconductor structure can also be achieved by the data read-write device, and will not be described in detail herein.

It should be understood that although the steps in the flowcharts of FIG. 1 to FIG. 4 are shown in turn as indicated by arrows, these steps are not necessarily performed in turn as indicated by the arrows. The execution order of these steps is not strictly limited, and these steps may be executed in other orders, unless clearly described otherwise. Moreover, at least some of the steps in FIG. 1 to FIG. 4 may include a plurality of sub-steps or stages. The sub-steps or stages are not necessarily executed at the same time, but may be executed at different times. The sub-steps or stages are not necessarily carried out sequentially, but may be executed alternately with other steps or at least some of sub-steps or stages of other steps.

The embodiments of this specification are described in a progressive manner, and each embodiment focuses on differences from other embodiments. The same or similar parts between the embodiments may refer to each other.

The technical characteristics of the above embodiments can be employed in arbitrary combinations. In an effort to provide a concise description of these embodiments, all possible combinations of all technical characteristics of the embodiments may not be described; however, these combinations of technical characteristics should be construed as disclosed in the description as long as no contradiction occurs.

The above embodiments are intended to illustrate several implementations of the present disclosure in detail, and they should not be construed as a limitation to the patentable scope of the present disclosure. It should be noted that those of ordinary skill in the art can further make several variations and improvements without departing from the conception of the embodiments of the present disclosure. These variations and improvements all fall within the protection scope of the present disclosure. Therefore, the protection scope of the present disclosure should be subject to the appended claims.

1. A semiconductor structure, comprising:
a substrate, a plurality of active regions separated from each other being formed in the substrate;
a trench, located in the active region;
a first gate structure, located in the trench, and configured to be applied with a first applied voltage;
a second gate structure, located in the trench, and located above the first gate structure, and configured to be applied with a second applied voltage, the second applied voltage being greater than the first applied voltage; and
an insulating isolation layer, located in the trench, and located between the first gate structure and the second gate structure.

2. The semiconductor structure according to claim 1, further comprising:
a first word line driver, electrically connected to the first gate structure, and configured to apply the first applied voltage to the first gate structure; and
a second word line driver, electrically connected to the second gate structure, and configured to apply the second applied voltage to the second gate structure.

3. The semiconductor structure according to claim 1, further comprising:
a gate oxide layer, located on a sidewall and a bottom of the trench, wherein the first gate structure, the insulating isolation layer and the second gate structure are all located on a surface of the gate oxide layer.

4. The semiconductor structure according to claim 1, further comprising:
a top dielectric layer, located in the trench, and located on the second gate structure.

5. The semiconductor structure according to claim 1, wherein there are a plurality of the trenches, and the plurality of the trenches are spaced apart.

6. The semiconductor structure according to claim 1, wherein the first gate structure comprises a first gate metal, and the first gate metal comprises at least one of titanium nitride, tungsten or polycrystalline silicon; and
the second gate structure comprises a second gate metal, and the second gate metal comprises at least one of titanium nitride, tungsten or polycrystalline silicon.

7. The semiconductor structure according to claim 1, wherein a thickness of the insulating isolation layer is in a range of 5 nm to 8 nm, and the insulating isolation layer comprises at least one of a silicon oxide layer or a silicon nitride layer.

8. The semiconductor structure according to claim 1, further comprising:
a source, located in the active region, and located at a side of the first gate structure and the second gate structure;
a source contact structure, electrically connected to the source;
a drain, located in a same active region with the source, and located at a side of the first gate structure and the second gate structure away from the source; and
a drain contact structure, electrically connected to the drain.

9. A method of manufacturing a semiconductor structure, comprising:
providing a substrate, a plurality of active regions separated from each other being formed in the substrate;
forming a plurality of trenches in the active regions;
forming a first gate structure, an insulating isolation layer and a second gate structure in the trench, wherein the second gate structure is located above the first gate structure, and the insulating isolation layer is located between the first gate structure and the second gate structure; and
forming a first word line driver and a second word line driver in the substrate, wherein the first word line driver is electrically connected to the first gate structure, and configured to apply a first applied voltage to the first gate structure; the second word line driver is electrically connected to the second gate structure, and configured to apply a second applied voltage to the second gate structure; and the second applied voltage is greater than the first applied voltage.

10. The method of manufacturing a semiconductor structure according to claim 9, wherein the forming a first gate structure, an insulating isolation layer and a second gate structure in the trench comprises:
forming a first gate metal in the trench and on an upper surface of the substrate;
removing a part of the first gate metal on the upper surface of the substrate and a part of the first gate metal in the trench, a remaining part of the first gate metal being the first gate structure;
depositing an insulating isolation material layer in the trench and on the upper surface of the substrate;
removing a part of the insulating isolation material layer on the upper surface of the substrate and a part of the insulating isolation material layer in the trench, a remaining part of the insulating isolation material layer being the insulating isolation layer;
depositing a second gate metal in the trench and on the upper surface of the substrate; and
removing a part of the second gate metal on the upper surface of the substrate and a part of the second gate metal in the trench, a remaining part of the second gate metal being the second gate structure.

11. The method of manufacturing a semiconductor structure according to claim 10, before the forming a first gate metal in the trench and on an upper surface of the substrate, further comprising:
forming a gate oxide layer on a sidewall and a bottom of the trench.

12. The method of manufacturing a semiconductor structure according to claim 11, wherein the forming a first gate structure, an insulating isolation layer and a second gate structure in the trench further comprises:
forming a top dielectric material layer on a surface of the second gate structure and a surface of the gate oxide layer; and
removing a part of the top dielectric material layer on the surface of the second gate structure and a part of the top dielectric material layer on the surface of the gate oxide layer, a remaining part of the top dielectric material layer being a top dielectric layer.

13. The method of manufacturing a semiconductor structure according to claim 9, after the forming a plurality of trenches in the active regions, and before the forming a first gate structure, an insulating isolation layer and a second gate structure in the trench, further comprising:
forming a source and a drain in the active region, the source and the drain being located at two opposite sides of the trench.

14. A data storage device, comprising the semiconductor structure according to claim 1.

15. A data read-write device, comprising the semiconductor structure according to claim 1.
